(19) United States
(12) Patent Application Publication
(10) Pub. No.: US 2012/0075038 A1
(43) Pub. Date: Mar. 29, 2012

(54) WIRING SUBSTRATE, FILTER DEVICE AND PORTABLE EQUIPMENT

(76) Inventor: Yasuhiro Kaizaki, Gifu (JP)

(21) Appl. No.: 13/322,686

(22) PCT Filed: Sep. 30, 2009
(86) PCT No.: PCT/JP2009/005051

§ 371 Date: Nov. 28, 2011

(30) Foreign Application Priority Data
May 28, 2009 (JP) 2009-129483

(51) Int. Cl. H01P 1/20; H05K 1/02; H05K 1/00

(52) U.S. Cl. 333/204; 174/250; 174/256

(57) ABSTRACT

In a wiring substrate, a wiring layer includes a pair of differential transmission lines. A conductive layer is provided on one side of the wiring layer. The conductive layer is grounded. An insulating layer is provided between the wiring layer and the conductive layer. The conductive layer includes a region, formed by an electrically continuous conductor, within a filter region. At least part of the conductor is turned around in the region. Seen from a stacking direction, the pair of differential transmission lines intersects with at least two strip portions disposed counter to each other because of the turning-around of the electrically continuous conductor.

### TECHNICAL FIELD

The present invention relates to a wiring substrate including differential transmission lines, a mobile device carrying said wiring substrate, and a filter device.

### BACKGROUND TECHNOLOGY

A differential transmission system, which is a transmission method less likely to be affected by electromagnetic noise, is generally in widespread use and is finding broader use in high-frequency applications. The differential transmission system is such that two phases of a signal, namely, a normal phase signal and a reverse phase signal, are produced from a single signal and they are transmitted using two signal lines. In this scheme, the phases of the normal phase signal and the reverse phase signal are inverted from each other in an ideal state (shifted by 180 degrees), so that they are in such a relationship as to cancel out their mutual magnetic fluxes. As a result, there will be smaller effects of inductance components on the lines. Hereinbelow, a mode in which signals are transmitted in this ideal state (with the phases of the normal phase signal and the reverse phase signal inverted from each other) in the differential transmission scheme is called a differential mode.

In actual circuits, however, there are many instances of somewhat upsetting balance between the normal phase signal and the reverse phase signal for reasons such as the difficulty of perfectly equalizing the length of the normal phase signal line where the normal phase signal flows and the length of the reverse phase signal line where the reverse phase signal flows. With the balance upset, signals in the same phase may flow on the normal phase signal line and the reverse phase signal line. Hereinbelow, a mode in which the signals in the same phase are transmitted on the two signal lines in the differential transmission system is called the common mode. That is, in actual circuitry, there are many cases where the two kinds of signals of the differential mode and the common mode are transmitted over the differential transmission line pair

A common-mode current that has occurred in a differential transmission line forms a loop passing through a path of mainly a grounding-side conductor, which is different from the differential transmission line. As the common-mode current flows through this loop, electromagnetic noise may be radiated. Also, as electromagnetic noise from outside enters this loop, the electromagnetic noise will be superposed on the differential transmission line. The amount of this noise radiation is proportional to the magnitude of the common-mode current and the area of the loop.

Conventionally, a so-called common-mode choke has been used to reduce the noise radiation by reducing the common-mode current. The common-mode choke is of such a structure that the normal phase signal line and the reverse phase signal line are wound around a doughnut-shaped ferrite core. In the way the lines are wound around the common-mode choke, the magnetic flux is canceled for the differential-mode current and therefore the impedance of the common-mode choke is low, whereas the magnetic flux is strengthened for the common-mode current and therefore the impedance of the common-mode choke is high. Thus, it is possible to efficiently attenuate or damp the common-mode signals only.

There are also propositions for constructing the common-mode choke in a multilayer structure for the purpose of downsizing (see Patent Document 1, Patent Document 2, and Patent Document 3).

### RELATED ART DOCUMENTS

### Patent Documents

[Patent Document 1] Japanese Unexamined Patent Application Publication No. 2004-311829.

[Patent Document 2] Japanese Unexamined Patent Application Publication No. 3545245.

[Patent Document 3] Japanese Unexamined Patent Application Publication No. 3863674.

### DISCLOSURE OF THE INVENTION

### Problems to be Solved by the Invention

In recent years, however, the tendency is the increased use of higher-frequency signals for electronic devices. Therefore, cases are arising where the common-mode choke having the ferrite core may not be suitable for the situation. It is because the ferrite does not allow easy maintenance of magnetic permeability at high-bandwidth frequencies, and in addition there is greater loss of the differential-mode signals at the common-mode choke in a high-frequency range. Especially with signals containing high-order harmonics of basic frequencies like digital signals, there are possibilities of waveform collapse in the differential mode due to the attenuation of the high-frequency components.

The present invention has been made in view of the foregoing problems, and a purpose thereof is to provide a technology for realizing a satisfactory bandpass characteristic even in a high-frequency range for a wiring substrate having a pair of differential transmission lines.

### Means for Solving the Problems

One embodiment of the present invention relates to a wiring substrate. The wiring substrate includes a wiring layer including a pair of differential transmission lines; a conductive layer where an electric potential thereof is fixed; and an insulating layer provided between the wiring layer and the conductive layer. The conductive layer has a region formed by an electrically continuous conductor. As seen from a stacking direction, the pair of transmission lines intersects with the conductor at a plurality of positions.

By employing this embodiment, common-mode signals can be filtered while the attenuation of differential-mode signals can be suppressed.

Another embodiment of the present invention relates also to a wiring substrate. The wiring substrate includes: a wiring layer including a pair of differential transmission lines; a conductive layer, where an electric potential thereof is fixed, provided on one side of the wiring layer; and an insulating layer provided between the wiring layer and the conductive layer; another conductive layer, where an electric potential thereof is fixed, provided on the other side of the wiring layer; and another insulating layer provided between the another conductive layer and the wiring layer. The conductive layer has a region formed by an electrically continuous conductor. As seen in a stacking direction, the pair of transmission lines intersects with the conductor at a plurality of positions. The another conductive layer has a region formed by another electrically continuous conductor. As seen in the stacking direction, the pair of transmission lines intersects with the another conductor at a plurality of positions.

By employing this embodiment, common-mode signals can be filtered while the attenuation of differential-mode signals can be suppressed.

Still another embodiment of the present invention relates to a filter device. The filter device includes: a wiring layer including a pair of differential transmission lines; a conductive layer where an electric potential thereof is fixed; an insulating layer provided between the wiring layer and the conductive layer; a first external terminal connected to one end of one of the differential transmission line pair, the first external terminal being exposed on a surface of the filter device; a second external terminal connected to the other end of one of the differential transmission line pair, the second external terminal being disposed on a surface of the filter device; a third external terminal connected to one end of the other of the differential transmission line pair, the third external terminal being exposed on a surface of the filter device; a fourth external terminal connected to the other end of the other of the differential transmission line pair, the fourth external terminal being disposed on a surface of the filter device; and a fifth external terminal connected to the conductive layer, the fifth external terminal being exposed on a surface of the filter device. The conductive layer has a region formed by an electrically continuous conductor. As seen in a stacking direction, the pair of transmission lines intersects with the conductor at a plurality of positions.

Still another embodiment of the present invention relates to a portable device. The portable device mounts the above-described wiring substrate.

By employing this embodiment, the performance of the portable device in a high frequency range is improved.

Optional combinations of the aforementioned constituting elements, and implementations of the invention in the form of methods, apparatuses, systems, and so forth may also be practiced as additional modes of the present invention.

### Effect of the Invention

The wiring substrate according to the present invention achieves a satisfactory pass characteristic in a high-frequency range.

### BRIEF DESCRIPTION OF THE DRAWINGS

FIG. 1 is a perspective view schematically showing a wiring substrate according to a first embodiment and an arrangement of modules mounted on the wiring substrate.

FIG. 2A and FIG. 2B each illustrates a structure of a filter region of FIG. 1.

FIG. 3 is a graph showing the results of simulation of a bandpass characteristic of a pair of differential transmission lines.

FIG. 4 is a top view of a filter region according to a first modification.

FIG. 5 is a graph showing the results of simulation of a bandpass characteristic of a pair of differential transmission lines according to a first modification.

FIG. 6 is a top view of a filter region according to a second modification.

FIG. 7 is a graph showing the results of simulation of a bandpass characteristic of a pair of differential transmission lines according to a second modification.

FIG. 8 is a perspective view schematically a wiring substrate according to a second embodiment and an arrangement of modules mounted on the wiring substrate.

FIG. 9A and FIG. 9B are each a top view of a filter region of FIG. 8.

FIG. 10 is a cross-sectional view taken along the line B-B of FIG. 8.

FIG. 11A and FIG. 11B are each a graph showing the results of simulation of a bandpass characteristic of a pair of differential transmission lines.

FIG. 12 is a perspective view showing a structure of a mobile phone equipped with the wiring substrate of FIG. 1.

FIG. 13 is a partial cross-sectional view of the mobile phone of FIG. 12.

FIG. 14A and FIG. 14B each illustrates a structure of a filter device.

FIG. 15 is a top view of a filter region according to a third modification of a first embodiment.

FIG. 16A and FIG. 16B are each a plan view of a filter region according to a second modification of a second embodiment seen from above.

FIG. 17 is a perspective view schematically showing a wiring substrate according to a third embodiment and an arrangement of modules mounted on the wiring substrate.

FIG. 18 is a cross-sectional view taken along the line C-C of FIG. 17.

FIG. 19 is an exploded perspective view showing a stacking structure inside a filter device.

### BEST MODE FOR CARRYING OUT THE INVENTION

The present invention will now be described based on preferred embodiments with reference to the accompanying drawings. The same or equivalent constituents and members illustrated in each drawing will be denoted with the same reference numerals, and the repeated descriptions thereof will be omitted as appropriate. The dimensions of the members in each drawing are illustrated by appropriately scaling the actual sizes thereof for ease of understanding.

Wiring substrates according to the preferred embodiments of the present invention are used preferably as substrates that are mounted on mobile devices such as mobile phones. Wiring substrates according to the embodiments described herein include a pair of differential transmission lines for transmitting high-frequency signals of 1 GHz and above and a common-mode filter region placed in its path and capable of filtering common-mode signals while reducing the attenuation of the differential-mode signals. In the common-mode filter region, a mutual impedance in the common mode is not enlarged by forming the pair of differential transmission lines in their respective coils, but the impedance in the common mode is enlarged by use of a difference between the capacity in the common mode and the capacity in the differential mode.

### First Embodiment

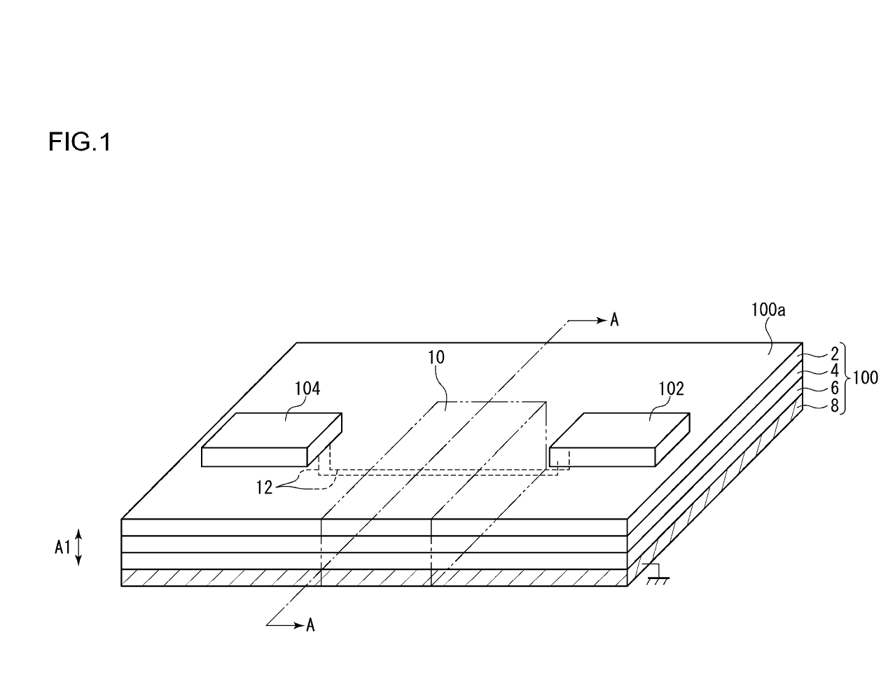

FIG. 1 is a perspective view schematically showing a wiring substrate 100 according to a first embodiment and an arrangement of modules mounted on the wiring substrate 100. A first semiconductor module 102 and a second semiconductor module 104 are mounted on a top surface 100a of the wiring substrate 100. In the following description, the side of the wiring substrate 100 on which the first semiconductor module 102 and the second semiconductor module 104 are mounted is assumed to be the upper side. Each of the first semiconductor module 102 and the second semiconductor module 104 is, for instance, a module packaging a die formed with an integrated circuit having a desired function.

The wiring substrate 100 includes a stacked structure stacking an electrical conducting layer 8 (hereinafter referred to as “conductive layer 8”), a second insulating layer 6, a wiring layer 4, and a first insulating layer 2 in this order from the lower side. This stacking direction is defined as stacking direction A1. In FIG. 1, the stacking direction A1 is a direction perpendicular to the top surface 100a of the wiring substrate 100. The wiring layer 4 includes a pair of differential transmission lines 12 for the exchange of high-frequency signals of 1 GHz and above between the first semiconductor module 102 and the second semiconductor module 104. The pair of differential transmission lines 12 passes across a filter region 10 (region delineated by two-dot chain lines in FIG. 1) of the wiring substrate 100. In the filter region 10, common-mode signals are filtered from the high-frequency signals transmitted through the pair of differential transmission lines 12. Note that the conductive layer 8 is grounded.

The first insulating layer 2 and the second insulating layer 6 are formed of an insulating material such as epoxy resin or alumina. The pair of differential transmission lines 12 and the conductive layer 8 are formed of a metal such as aluminum, gold, copper, silver-platinum (AgPt), or silver-palladium (AgPd). The thickness of the first insulating layer 2 is about 40 μm, the thickness of the wiring layer 4 is about 18 μm, the thickness of the second insulating layer 6 is about 40 μm, and the thickness of the conductive layer 8 is about 18 μm.

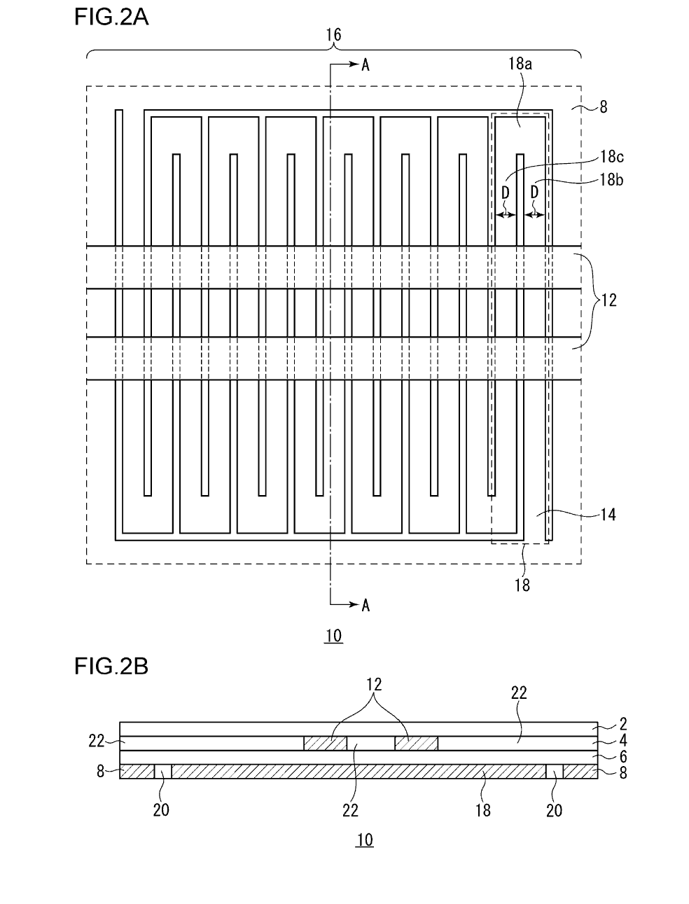

FIG. 2A is a plan view (hereinafter referred to as “top view” also) of the filter region 10 as seen from the top surface 100a. In FIG. 2A, the depiction of insulating material is omitted. The line A-A in FIG. 2A corresponds to the line A-A in FIG. 1. FIG. 2B is a cross-sectional view taken along the line A-A of FIG. 2A.

The conductive layer 8 has a region 16 formed by an electrically continuous conductor line 14. The electrically continuous conductor line 14 is, for instance, a conductor line whose thickness in the stacking direction A1 is shorter than its width in a surface direction (the cross-sectional shape thereof being a horizontally-long rectangle). It is to be noted, however, that the cross-sectional shape of the electrically continuous conductor line 14 may be a trapezoid, a mountain shape, or a vertically-long rectangle. The mountain shape herein should be understood to include trapezoids and other trapezoidal shapes having continuously changing curvatures for the not parallel sides thereof. The conductor line 14 is part of a metal forming the conductive layer 8 and is therefore grounded. In the region 16, the conductor line 14 is formed in a meandering or other repeated pattern. In the region 16 shown in FIG. 2A, the conductor line 14 is in a pattern having unit patterns 18 repeated in the direction parallel to the pair of differential transmission lines 12 (horizontal direction in the figure, also applicable hereafter). The unit pattern 18, which is turned around on the way, includes a turned-around portion 18a, one strip portion 18b, and the other strip portion 18c. The one strip portion 18b and the other strip portion 18c have the same width D. The width D is designed to be about 100 μm, for instance. The clearance gap between the one strip portion 18b and the other strip portion 18c is designed to be about 40 μm. Seen from above in the stacking direction A1, the pair of differential transmission lines 12 intersects with the one strip portion 18b and the other strip portion 18c, which are disposed counter to each other because of the turning-around.

In FIG. 2B, the depiction of components other than the filter region 10 is omitted. The wiring layer 4 includes a pair of differential transmission lines 12 and insulators 22 of epoxy resin or the like. Insulators 20 of epoxy resin or the like fill the clearance gaps of the conductor line 14.

The wiring substrate 100 according to the first embodiment is so arranged that in the filter region 10, the pair of differential transmission lines 12 is opposed to the electrically continuous conductor line 14 formed in a repeated pattern. Further, seen from above in the stacking direction A1, the pair of differential transmission lines 12 intersects with the one strip portion 18b and the other strip portion 18c, which are opposite to each other because of the turning-around. Therefore, because of this structure, common-mode signals can be filtered over a wide bandwidth from high-frequency signals of 1 GHz and above. Also, there will be substantially no attenuation of differential-mode signals.

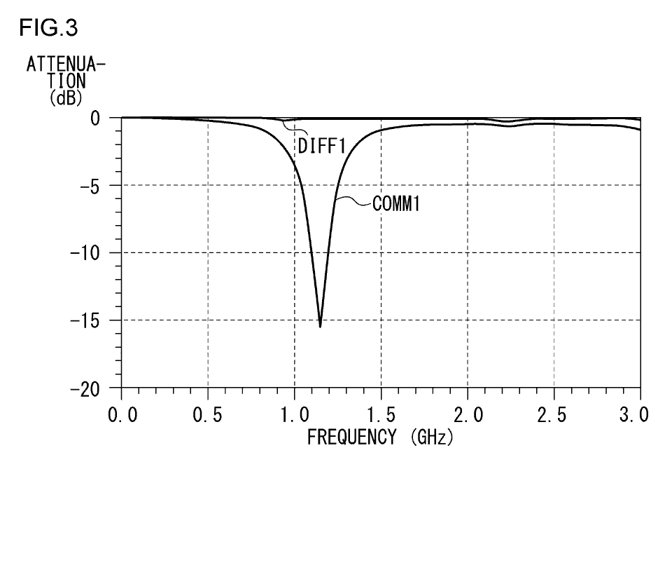

FIG. 3 is a graph showing the results of simulation of the bandpass characteristic of the pair of differential transmission lines 12. In FIG. 3, the horizontal axis represents the frequencies (GHz) of signals passing through the pair of differential transmission lines 12, and the vertical axis represents the degree of attenuation of the current components in each mode in the filter region 10. Whereas COMM1 shows how the common-mode signals are attenuated, DIFF1 shows how the differential-mode signals are attenuated. As is evident from FIG. 3, the attenuation of the differential-mode signals is at a negligible level in the high-frequency band of 1 GHz and above, and the common-mode signals are attenuated over a relatively wide bandwidth.

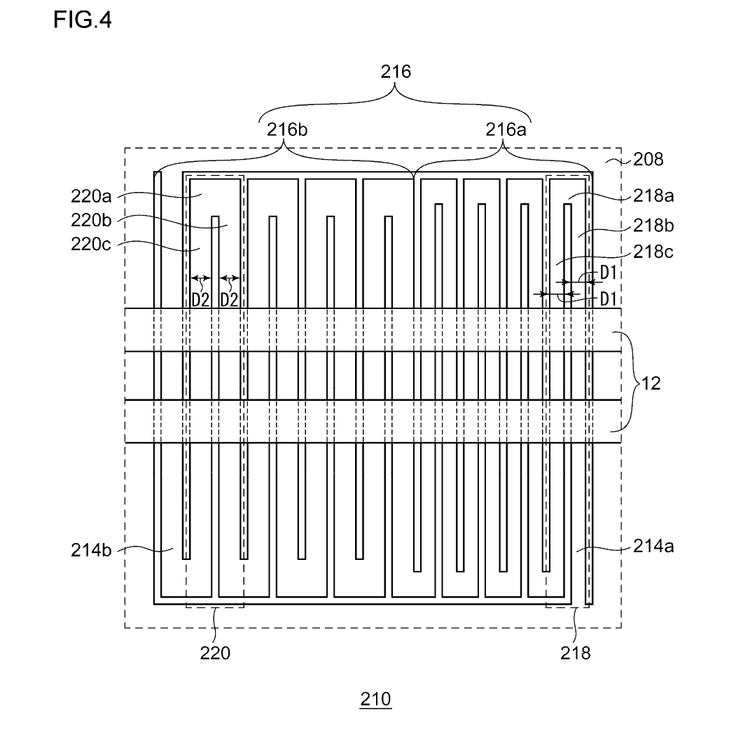

Two modifications of the filter region 10 will be explained. FIG. 4 is a top view of a filter region 210 according to a first modification of the first embodiment. In FIG. 4, the depiction of insulating material is omitted. The difference between the filter region 10 according to the first embodiment and the filter region 210 according to the first modification lies in the shape of the electrically continuous conductor line in the regions 16 and 216.

A conductive layer 208 includes a first region 216a formed by an electrically continuous first conductor line 214a and a second region 216b formed by an electrically continuous second conductor line 214b. The first region 216a and the second region 216b together constitute the region 216. The width D1 of the first conductor line 214a may be different from the width D2 of the second conductor line 214b such that D1<D2 or D1>D2, for instance.

In the first region 216a, the first conductor line 214a includes a pattern of first unit patterns 218 repeated in the direction parallel to the pair of differential transmission lines 12. The first unit pattern 218, which is turned around on the way, includes a turned-around portion 218a, one strip portion 218b, and the other strip portion 218c. The one strip portion 218b and the other strip portion 218c have the same width D1. The width D1 is designed to be about 100 μm. The clearance gap between the one strip portion 218b and the other strip portion 218c is designed to be about 40 μm. Seen from above in the stacking direction A1, the pair of differential transmission lines 12 intersects with the one strip portion 218b and the other strip portion 218c, which are opposite to each other because of the turning-around.

In the second region 216b, the second conductor line 214b includes a pattern of second unit patterns 220 repeated in the direction parallel to the pair of differential transmission lines 12. The second unit pattern 220, which is turned around on the way, includes a turned-around portion 220a, one strip portion 220b, and the other strip portion 220c. The one strip portion 220b and the other strip portion 220c have the same width D2. The width D2 of the one strip portion 220b and the other strip portion 220c is larger than the width D1 of the one strip portion 218b and the other strip portion 218c. The width D2 is designed to be about 150 μm. The clearance gap between the one strip portion 220b and the other strip portion 220c is designed to be about 40 μm. Seen from above in the stacking direction A1, the pair of differential transmission lines 12 intersects with the one strip portion 220b and the other strip portion 220c, which are opposite to each other because of the turning-around.

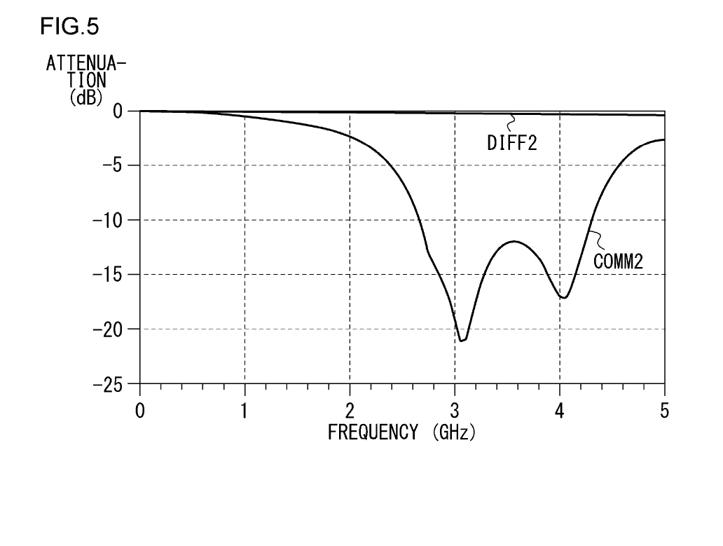

By employing the wiring substrate having the filter region 210 according to the first modification, the common-mode signals can be attenuated over a wider bandwidth as compared with the wiring substrate 100 according to the first embodiment. FIG. 5 is a graph showing the results of simulation of the bandpass characteristic of the pair of differential transmission lines 12 according to the first modification. In FIG. 5, the horizontal axis represents the frequencies (GHz) of signals passing through the pair of differential transmission lines 12, and the vertical axis represents the degree of attenuation of the current components in each mode in the filter region 210. Whereas COMM2 shows how the common-mode signals are attenuated, DIFF2 shows how the differential-mode signals are attenuated. As is evident from FIG. 5, the attenuation of the differential-mode signals is at a negligible level in the high-frequency band of 1 GHz and above. Also, two peaks of attenuation appear in the common-mode signals. These two peaks of attenuation are contributable to the fact that the region 216 has the first region 216a and the second region 216b where the width of the strip portions in the first region 216 differs from that in the second region 216b. It is found that, on the whole, having two separate peaks of attenuation like this enables the common-mode signals to be attenuated over a wider bandwidth than in the case of the first embodiment. Thus, the first modification is preferable in a case where it is desirable that the common-mode signals be attenuated over a wider bandwidth.

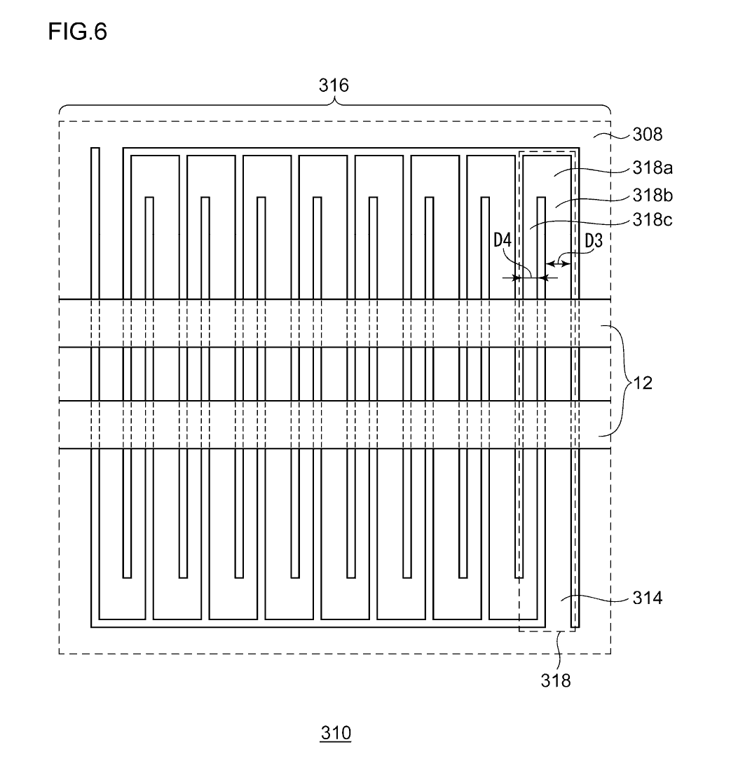

The above-described two separate peaks of attenuation occur because the electrically continuous conductor line has two different widths. A description is therefore given hereunder of a case where the line width is made to differ in the unit pattern. FIG. 6 is a top view of a filter region 310 according to a second modification. In FIG.6, the depiction of insulating material is omitted. The difference between the filter region 10 according to the first embodiment and the filter region 310 according to the second modification lies in the shape of the electrically continuous conductor line in the regions 16 and 316.

A conductive layer 308 includes a region 316 formed by an electrically continuous conductor line 314. In the region 316, the conductor line 314 includes a pattern of unit patterns 318 repeated a plurality of times in the direction parallel to the pair of differential transmission lines 12. The unit pattern 318, which is turned around on the way, includes a turned-around portion 318a, one strip portion 318b, and the other strip portion 318c. The width D3 of the one strip 318b may be different from the width D4 of the other strip portion 318c such that D3>D4 or D4<D3, for instance. The width D3 is designed to be about 150 μm, and the width D4 is designed to be about 100 μm. The clearance gap between the one strip portion 318b and the other strip portion 318c is designed to be about 40 μm. In other words, a plurality of strip portions in the region 316 are formed such that a strip portion having the width D3 and a strip portion having the width D4 are formed alternately. Seen from above in the stacking direction A1, the pair of differential transmission lines 12 intersects with the one strip portion 318b and the other strip portion 318c, which are opposite to each other because of the turning-around.

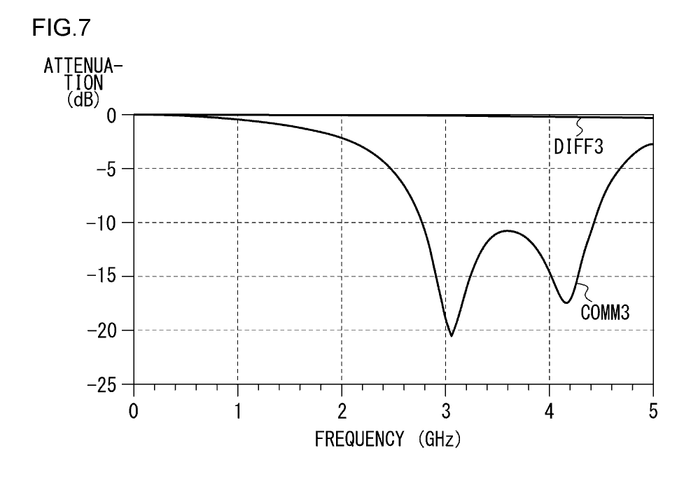

By employing the wiring substrate having the filter region 310 according to the second modification, similarly to the first modification, the common-mode signals can be attenuated over a wider bandwidth as compared with the wiring substrate 100 according to the first embodiment. FIG. 7 is a graph showing the results of simulation of the bandpass characteristic of the pair of differential transmission lines 12 according to the second modification. In FIG. 7, the horizontal axis represents the frequencies (GHz) of signals passing through the pair of differential transmission lines 12, and the vertical axis represents the degree of attenuation of the current components in each mode in the filter region 310. Whereas COMM3 shows how the common-mode signals are attenuated, DIFF3 shows how the differential-mode signals are attenuated. As is evident from FIG. 7, similarly to the first modification, two separate peaks of attenuation also appear in the second modification. Thus, on the whole, the common-mode signals is attenuated over a wider bandwidth than in the first embodiment. The second modification is also preferable in the case where it is desirable that the common-mode signals be attenuated over a wider bandwidth.

### Second Embodiment

In the first embodiment, a description has been given of the case where the conductive layer 8 is provided on one side of the wiring layer 4 including a pair of differential transmission lines 12. In a second embodiment, a conductive layer is provided on the other side of the wiring layer 4 in addition to the aforementioned conductive layer 8.

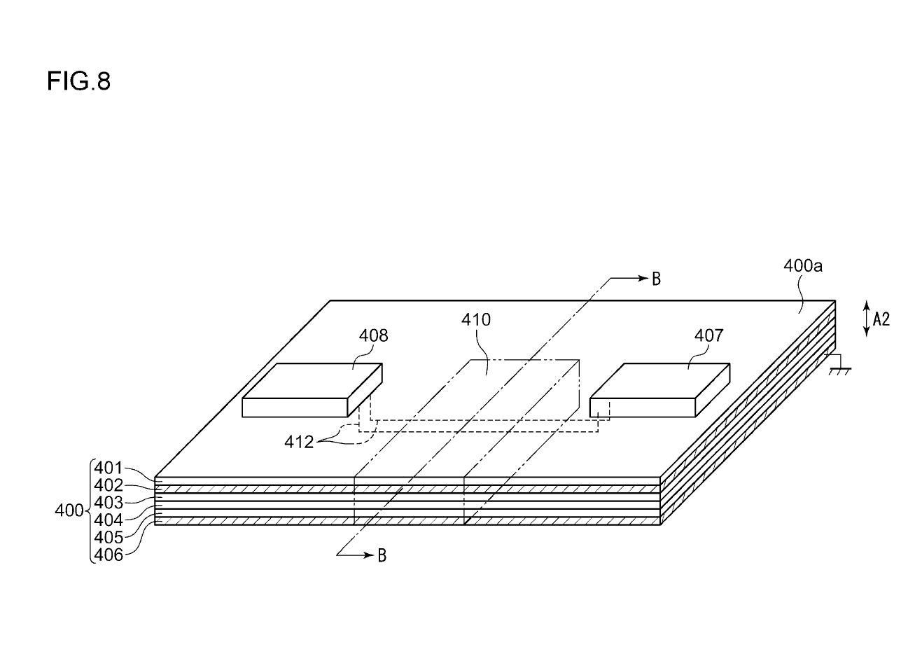

FIG. 8 is a perspective view schematically a wiring substrate 400 according to the second embodiment and an arrangement of modules mounted on the wiring substrate 400. A first semiconductor module 407 and a second semiconductor module 408 are mounted on a top surface 400a of the wiring substrate 400. In the following description, the side of the wiring substrate 400 on which the first semiconductor module 407 and the second semiconductor module 408 are mounted is assumed to be the upper side. Each of the first semiconductor module 407 and the second semiconductor module 408 is a module similar to each of the modes in the first embodiment.

The wiring substrate 400 includes a stacked structure stacking a second conductive layer 406, a third insulating layer 405, a wiring layer 404, a second insulating layer 403, a first conductive layer 402, and a first insulating layer 401 in this order from the lower side. This stacking direction is defined as stacking direction A2. In FIG. 8, the stacking direction A2 is a direction perpendicular to the top surface 400a of the wiring substrate 400. The wiring layer 404 includes a pair of differential transmission lines 412 between the first semiconductor module 407 and the second semiconductor module 408. The pair of differential transmission lines 412 passes across a filter region 410 (region delineated by two-dot chain lines in FIG. 8) of the wiring substrate 400. In the filter region 410, common-mode signals are filtered from the high-frequency signals transmitted through the pair of differential transmission lines 412. Note that the second conductive layer 406 is grounded. Though discussed later, the first conductive layer 402 and the second conductive layer 406 are electrically connected to each other by a via (not shown) provided in the filter region 410. Thus, the first conductive layer 402 is grounded by way of the via and the second conductive layer 406.

The first insulating layer 401, the second insulating layer 403 and the third insulating layer 405 are formed of an insulating material such as epoxy resin or alumina. The pair of differential transmission lines 412, the first conductive layer 402 and the second conductive layer 406 are formed of a metal such as aluminum, gold, copper, silver-platinum (AgPt), or silver-palladium (AgPd). The thickness of the first insulating layer 401 is about 40 μm, the thickness of the first conductive layer 402 is about 18 μm, the thickness of the second insulating layer 403 is about 40 μm, the thickness of the wiring layer 404 is about 18 μm, the thickness of the third insulating layer 405 is about 40 μm, and the thickness of the second conductive layer 406 is about 18 μm.

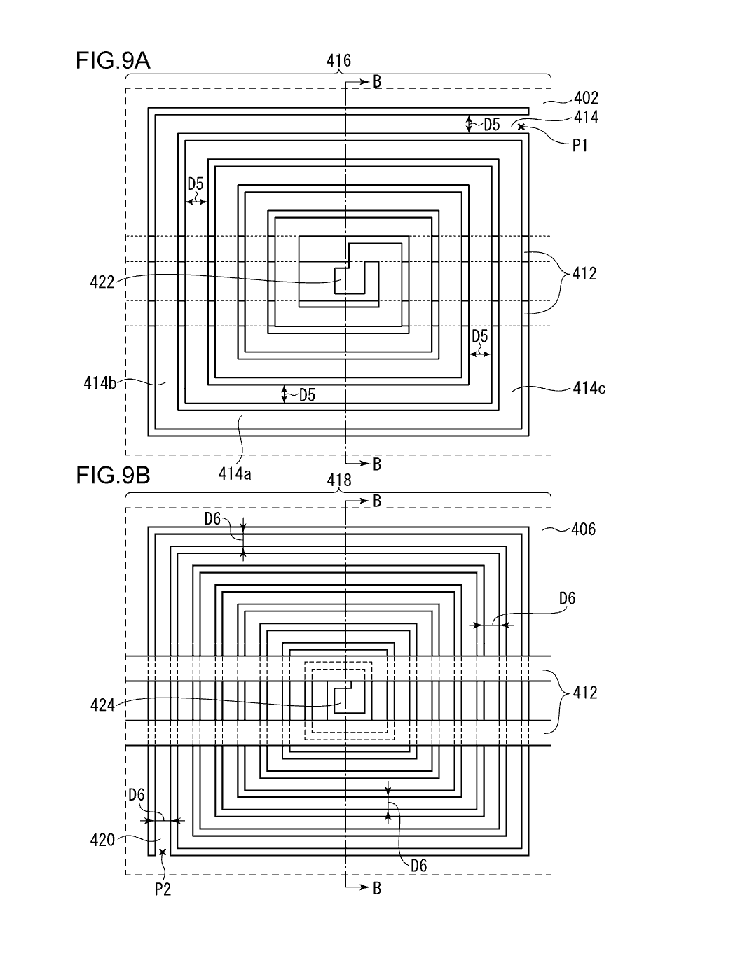

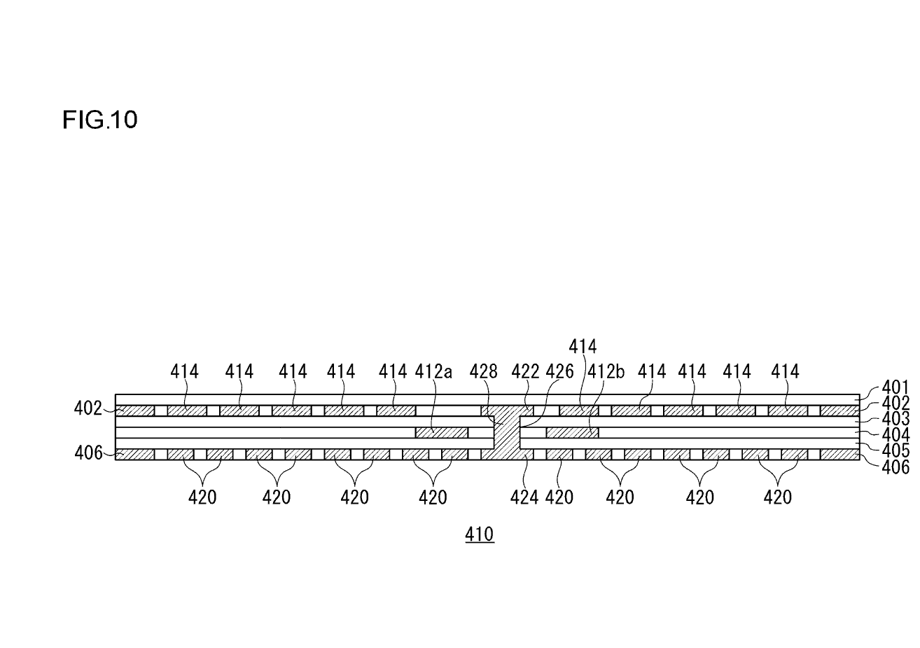

FIG. 9A and FIG. 9B are each a plan view showing the filter region 410. In FIGS. 9A and 9B, the depiction of insulating material is omitted. FIG. 9A is a top view thereof where the depiction of the filter region 410 other than the first conductive layer 402 and the wiring layer 404 is omitted. FIG. 10 is a cross-sectional view taken along the line B-B of FIGS. 9A and 9B

The first conductive layer 402 has a first region 416 formed by an electrically continuous first conductor line 414. The electrically continuous first conductor line 414 is, for instance, a conductor line whose thickness in the stacking direction A2 is shorter than its width in a surface direction. The cross-sectional shape of the electrically continuous first conductor line 414 is similar to that of the electrically continuous conductor line 14. The first conductor line 414 is part of a metal forming the first conductive layer 402. In the region 416, the first conductor line 414 has a uniform width of D5. The first conductor line 414 extends leftward from a starting point P1 shown in FIG. 9A and returns around 90 degrees downward near a leftmost point of the first region 416. Then the first conductor line 44 further extends downward and returns around 90 degrees rightward near a lower end of the first region 416. Then the first conductor line 414 further extends rightward and returns back 90 degrees upward near a rightmost point of the first region 416. Then the first conductor line 414 extends upward just before it reaches the first conductor line 414 itself extending from the starting point P1 and then returns back 90 degrees leftward there. The same procedure as above continues, and the first conductor line 414 extends helically counterclockwise until the first conductor line 414 reaches a first via land 422 located at the center of the first region 416. The width D5 is designed to be about 150 μm and the clearance gap between adjacent conductor lines is designed to be about 40 μm. The pair of differential transmission lines 412 passes under the first region 416, namely under the sheet surface thereof in FIG. 9A. In this case, when attention is directed to a turned-around portion 414a, one strip portion 414b and the other strip portion 414c shown in FIG. 9A, for instance, one observes that, as seen from above, the pair of differential transmission lines 412 intersects with the one strip portion 414b and the other strip portion 414c, which are opposite to each other because the first conductor line 414 is turned around at the turned-around portion 414a.

FIG. 9B is a top view thereof where the depiction of the filter region 410 other than the wiring layer 404, the second conductive layer 406 and the pair of differential transmission lines 412 is omitted. The second conductive layer 406 has a second region 418 formed by an electrically continuous second conductor line 420. The second region 418 has the same structure as that of the first region 416 shown in FIG. 9A. The difference is that the helix of the second conductor line 420 in the second region 418 of FIG. 9B is wound clockwise while the helix of the first conductor line 414 in the first region of FIG. 9A is wound counterclockwise. Also, the pair of differential transmission lines 412 passes above the second region 412, namely above the sheet surface of the second region 418 in FIG. 9B. The width D6 of the second conductor line 420 may be different from the width D5 of the first conductor line 414 such that D6<D5 or D6>D5. The width D6 is designed to be about 100 μm.

The via land 422 located at the center of the helix of the first conductor line 414 in the first region 416 is electrically connected to a second via land 424 located at the center of the helix of the second conductor line 420 in the second region 418 of FIG. 9B by a via (not shown in FIGS. 9A and 9B) which penetrates the second insulating layer 403, the wiring layer 404 and the third insulating layer 405.

In FIG. 10, components other than the filter region 410 are omitted. In the second insulating layer 403, the wiring layer 404 and the third insulating layer 405, a via hole 426 that penetrates from the first via land 422 to the second via land 424 is provided between one transmission line 412a of the pair of differential transmission lines 412 and the other transmission line 412b thereof. A via 428 is formed of a metal such as copper, and the first via land 422 and the second via land 424 are electrically connected to each other thereby. Thus, the first conductive layer 402 and the second conductor layer 406 are electrically connected to each other. Such connection as this means that an electric path having a starting point P1 (FIG. 9A) in the first conductor line 414 and having an end point P2 (FIG. 9B) in the second conductor line 420 is formed in the filter region 410 by way of the via 428.

By employing the wiring substrate 400 according to the second embodiment, in the filter region 410, the pair of transmission lines 412 is disposed counter to the electrically continuous conductor line 414 which is helical in shape and the electrically continuous conductor line 420 which is also helical in shape. Thus, the common-mode signals can be filter over a wider bandwidth. Also, there will be substantially no attenuation of differential-mode signals.

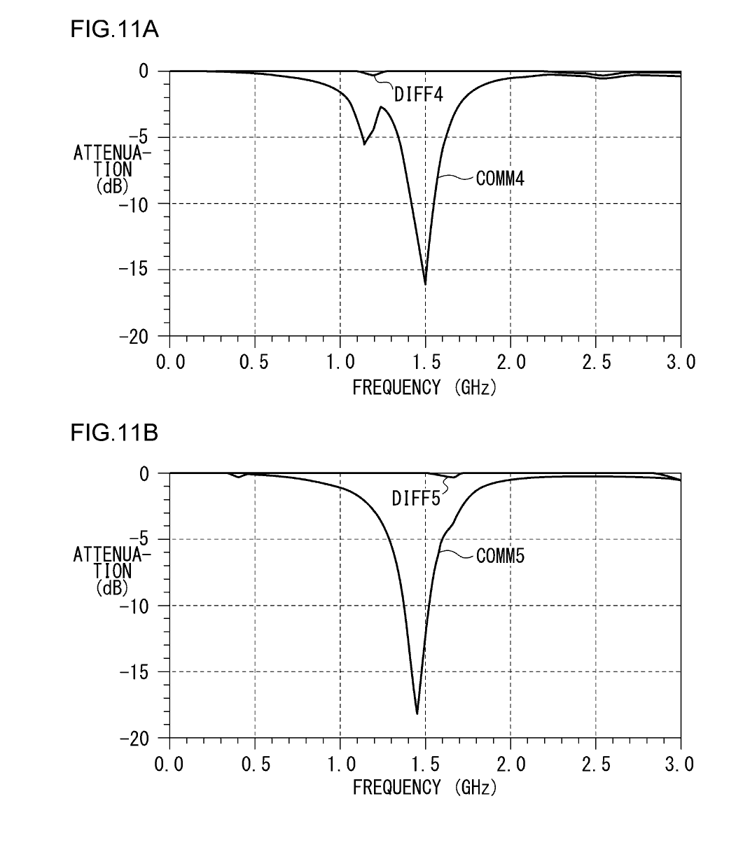

FIG. 11A and FIG. 11B are each a graph showing the results of simulation of a bandpass characteristic of the pair of differential transmission lines 412. In FIGS. 11A and 11B, the horizontal axis represents the frequencies (GHz) of signals passing through the pair of differential transmission lines 412, and the vertical axis represents the degree of attenuation of the current components in each mode in the filter region 410. FIG. 11A is a graph showing the results of simulation of a bandpass characteristic of the pair of differential transmission lines 412 according to the second embodiment. Whereas COMM4 shows how the common-mode signals are attenuated, DIFF4 shows how the differential-mode signals are attenuated. As is evident from FIG.11A, the attenuation of the differential-mode signals is at a negligible level in the high-frequency band of 1 GHz and above. Similarly to FIG. 5 and FIG. 7, two separate peaks of attenuation appear in the common-mode signals. The these two peaks of attenuation are attributable to the fact that the width D5 of the first conductor line 414 and the width D6 of the second conductor line 420 differ from each other. It is found that, on the whole, having two separate peaks of attenuation like this enables the common-mode signals to be attenuated over a wider bandwidth than in the first embodiment. Thus, the second embodiment is preferable in a case where it is desirable that the common-mode signals be attenuated over a wider bandwidth.

Now, consider a case, where no via 428 is provided, as a first modification of the second embodiment. FIG. 11B is a graph showing the results of simulation of the bandpass characteristic of the pair of differential transmission lines 412. COMM5 shows how the common-mode signals are attenuated, and DIFF5 shows how the differential-mode signals are attenuated. As is evident from FIG.11B, when no via 428 is provided, there is only a single peak of attenuation in the common mode and the bandwidth of filter is reduced. At the same time, the peak of attenuation becomes larger (deeper). That is, the degree of attenuation is strengthened. Hence, this first modification of the second embodiment is preferable and serves its purpose because when the frequency band to be filtered is narrow, the common-mode signals can be attenuated stronger than in a case of the second embodiment.

(Application to Mobile Device)

Next, a description will now be given of a mobile device or portable device provided with the above-described wiring substrate. The mobile device presented as an example herein is a mobile phone, but it may be any electronic apparatus, such as a personal digital assistant (PDA), a digital video cameras (DVC), a music player, and a digital still camera (DSC).

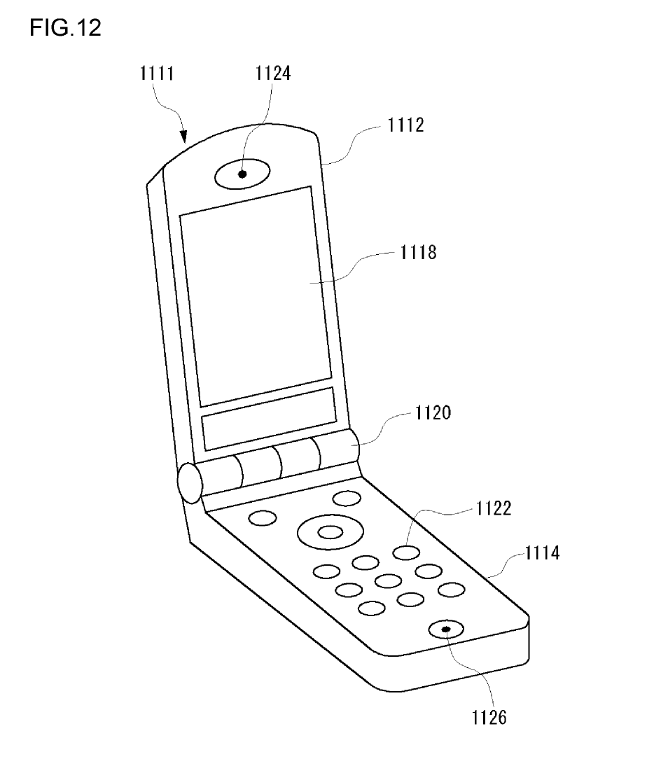

FIG. 12 is a perspective view showing a structure of a mobile phone 1111 equipped with the wiring substrate 100 according to the first embodiment. The mobile phone 1111 has a structure including a first casing 1112 and a second casing 1114 jointed together by a movable part 1120. The first casing 1112 and the second casing 1114 are turnable/rotatable around the movable part 1120 as the axis. The first casing 1112 is provided with a display unit 1118 for displaying characters, images and other information and a speaker unit 1124. The second casing 1114 is provided with a control module 1122 with operation buttons and the like and a microphone 126. The wiring substrate 100 according to the first embodiment is mounted within the mobile phone 1111. Examples of the first semiconductor module 102 and the second semiconductor module 104 mounted on the wiring substrate 100 in the mobile phone 1111 may include a power circuit for driving each circuit, a transmit/receive circuit connected to an antenna (not shown), a signal processing circuit such as a DAC or an encoder circuit, a driver circuit for a backlight used as the light source of a liquid-crystal panel used for a display of the mobile phone, and the like.

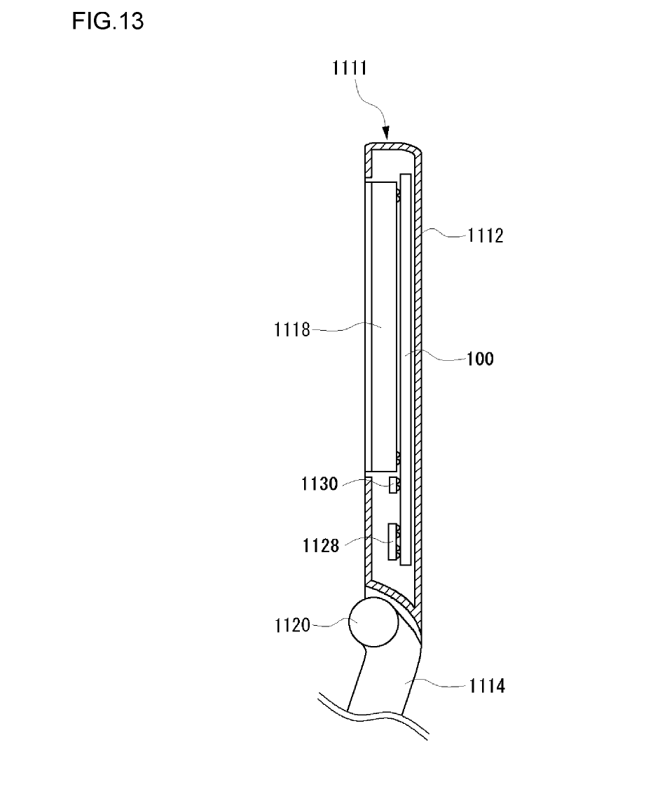

FIG. 13 is a partial cross-sectional view (cross-sectional view of the first casing 1112) of the mobile phone 1111 shown in FIG. 12. A transmit/receive circuit 1128 and a signal processing circuit 1130 are mounted on the wiring substrate 100. The wiring substrate 100 includes a pair of differential transmission lines for the exchange of high-frequency signals of 1 GHz and above between the transmit/receive circuit 1128 and the signal processing circuit 1130.

The transmission characteristics of signals between the circuit modules included in the mobile phone 1111 (for instance, between the transmit/receive circuit 1128 and the signal processing circuit 1130) particularly in the high-frequency range of 1 GHz and above can be improved by employing the mobile phone 1111 equipped with the wiring substrate 100 of the first embodiment. Thus the wiring substrate according to the first embodiment is preferably used for a mobile device that handles the high-frequency signals of 1 GHz and above.

The same advantageous effects can be achieved by mounting the wiring substrate 400 according to the second embodiment on the mobile phone.

(Application to Filter Device)

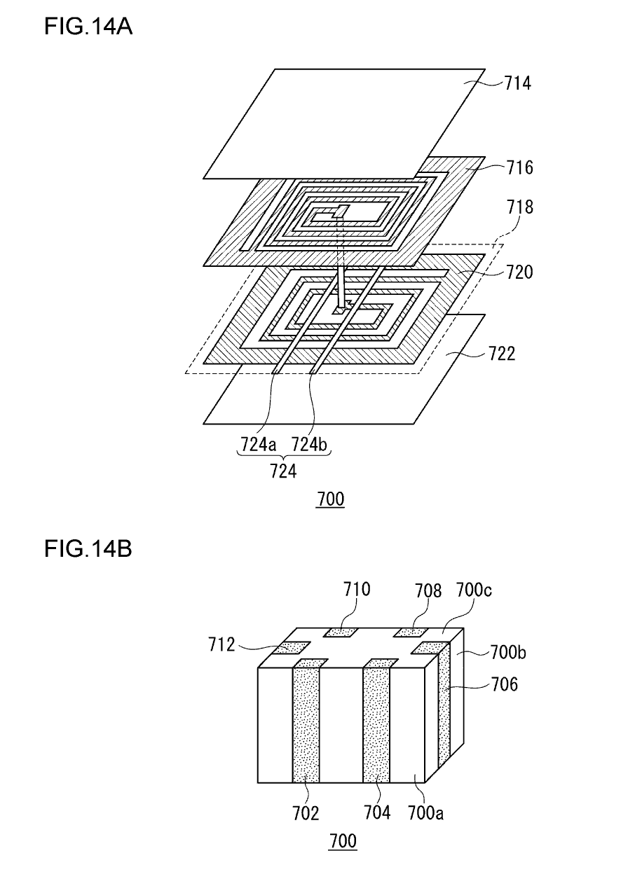

FIG. 14A is an exploded perspective view showing a stack structure inside a filter device 700. FIG. 14B is a perspective view showing a structure of the filter device 700. In FIG. 14A, the depiction of insulating materials other than a first insulating layer 714 and a fourth insulating layer 722 is omitted.

The filter device 700 is a chip-type device having a stack structure similar to that of the filter region 410 of the wiring substrate 400 according to the second embodiment. The filter device 700 is suited for use as a replacement part to be mounted at an arbitrary position on the wiring board, especially as a replacement part for the differential transmission lines.

The filter device 700 includes a stacked structure stacking a fourth insulating layer 722, a second conductive layer 720, a wiring layer 718, a first conductive layer 716, and a first insulating layer 714 in this order from the lower side. This stack structure of the filter device 700 corresponds to the stack structure of the filter region 410 of the wiring substrate 400 according to the second embodiment except that the fourth insulating layer 722 is placed below the second conductive layer 720. In other words, the second conductive layer 720 corresponds to the second conductive layer 406, the wiring layer 718 corresponds to the wiring layer 404, the first conductive layer 716 corresponds to the first conductive layer 402, and the first insulating layer 714 corresponds to the first insulating layer 401, respectively. It is to be noted that, although not shown in FIG. 14A, a second insulating layer corresponding to the second insulating layer 403 is placed on the upper side of the wiring layer 718, and a third insulating layer corresponding to the third insulating layer 405 is placed on the lower side thereof.

The filter device 700 is provided with first to sixth conductor pads 702 to 712 to effect electrical connection of each of the pair of differential transmission lines 724, the first conductive layer 716, and the second conductive layer 720 with the outside. For convenience of explanation, a front side 700a, a right side 700b, and a top side 700c of the filter device 700 are defined as shown in FIG. 14b.

On the front side 700a of the filter device 700, the first conductor pad 702 and the second conductor pad 704 are formed in such a manner as to be exposed there. The first conductor pad 702 is connected to one end of one transmission line 724a of the pair of differential transmission lines 724. The second conductor pad 704 is connected to one end of the other transmission line 724b of the pair of differential transmission lines 724. On the back side (not shown) of the filter device 700, the third conductor pad 710 and the fourth conductor pad 708 are formed in such a manner as to be exposed there. The third conductor pad 710 is connected to the other end of one transmission line 724a of the pair of differential transmission lines 724. The fourth conductor pad 708 is connected to the other end of the other transmission line 724b of the pair of differential transmission lines 724.

On the right side 700b of the filter device 700, the fifth conductor pad 706 is formed in such a manner as to be exposed there. The fifth conductor pad 706 is connected to the first conductive layer 716. As for the second conductive layer 720, the sixth conductor pad 712 may be formed in such a manner as to be exposed on the left side (not shown) of the filter device 700, and the second conductive layer 720 may be connected to the sixth conductor pad 712. Also, no sixth conductor pad 712 may be provided, and instead both the first conductive layer 716 and the second conductive layer 720 may be connected in common to the fifth conductor pad 706. That is, the sixth conductor pad 712 is not an essential constituent part for the filter device 700.

This filter device 700 provides advantageous effects similar to those of the wiring substrate 400 according to the second embodiment. In addition, the filter device 700 can realize a chip-type common-mode filter as a replacement part to be mounted at an arbitrary position on a circuit substrate, especially as a replacement part for the differential transmission lines. Also, the chip form contributes to the downsizing of semiconductor devices.

The present invention is not limited to the above-described embodiments only, and it is understood by those skilled in the art that various modifications such as changes in design may be made based on their knowledge and the embodiments added with such modifications are also within the scope of the present invention.

In the first embodiment, a description has been given of a case where the conductive layer, the insulating layer, the wiring layer, and the insulating layer are stacked in this order from the lower side, but the stacking order is not limited thereto. For example, the wiring layer, the insulating layer, the conductive layer, and the insulating layer may be stacked in this order from the lower side.

In the first and second embodiments including the modifications thereof, a description has been given of a case where the wiring substrate includes a pair of differential transmission lines for transmitting high-frequency signals of 1 GHz and above, but this should not be considered as limiting. The embodiments and their modifications can also be applied to a case where signals of 400 MHz and above are transmitted through a pair of differential transmission lines. It is to be noted, however, that the advantageous effects of the embodiments and their modifications are particularly marked for signals in a GHz frequency band.

Also, the reference of “helical” herein is not limited to the shape that is formed of the electrically continuous conductor line in the first region 416 and the second region 418 as described in the second embodiment by turning around the straight line by 90 degrees repeatedly in two dimensions. The electrically continuous conductor line may be formed in a curve, for example, in a two-dimensional spiral shape.

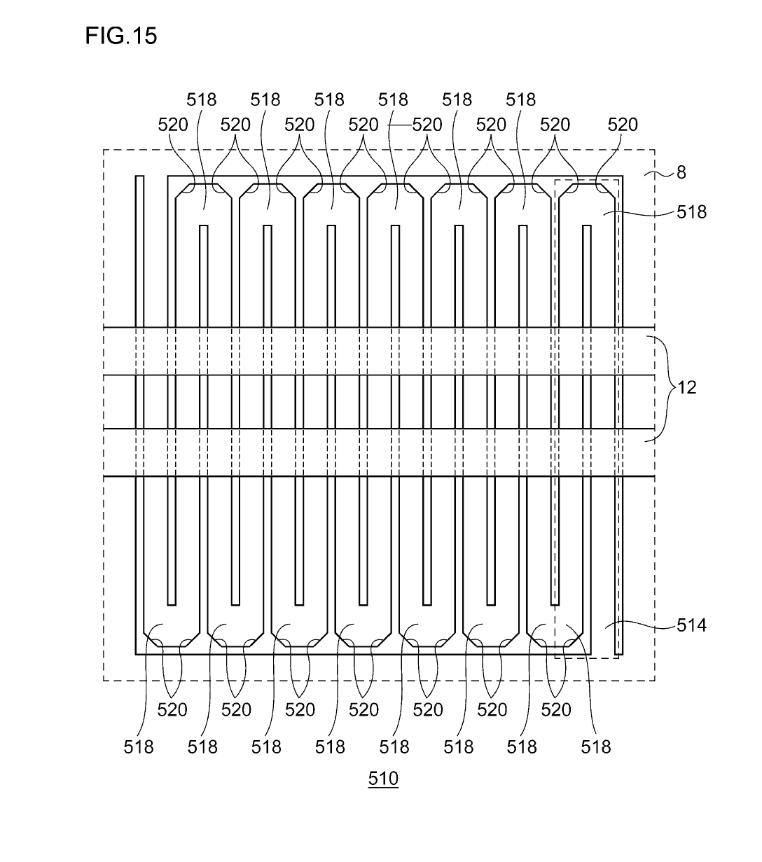

In the first and second embodiments, a description has been given of a case where the electrically continuous conductor line has the turned-around portion with angles of about 90 degrees, but the arrangement is not limited thereto. For example, the angles of the turned-around portion may be truncated. FIG. 15 is a top view of a filter region 510 according to a third modification of the first embodiment. Tapers 520 of about 45 degrees are given to the angles of a turned-around portion 518 of an electrically continuous conductor line 514.

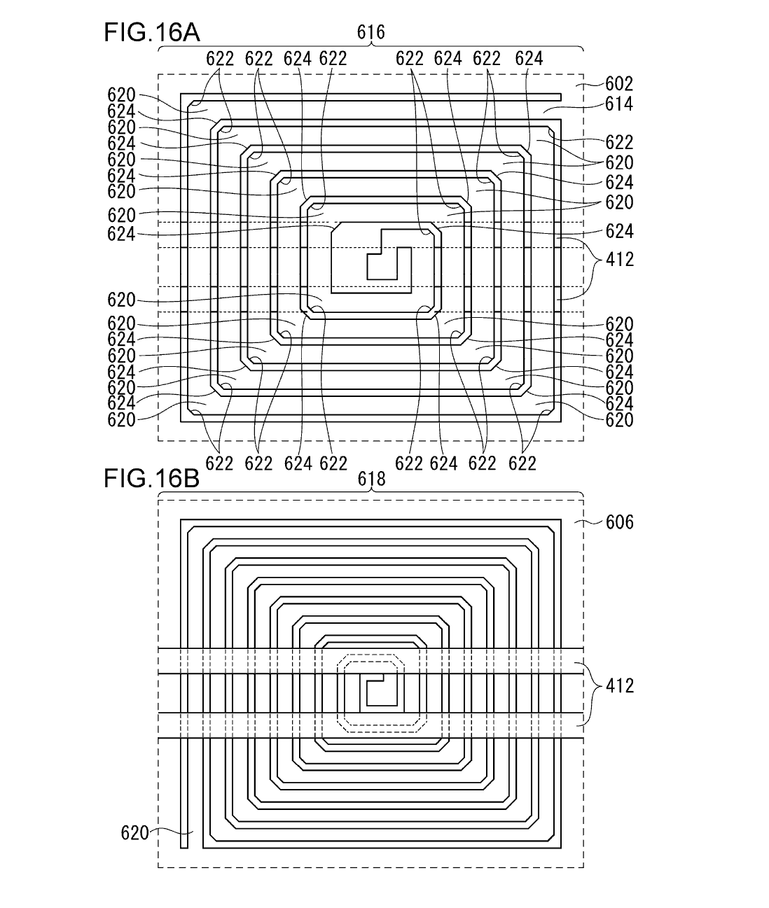

FIGS. 16A and 16B are plan views of a filter region according to a second modification of the second embodiment seen from above. FIG. 16A is a top view of the filter region omitting the components other than a first conductive layer 602 and the wiring layer 404. FIG. 16B is a top view of the filter region omitting the components other than the wiring layer 404 and a second conductive layer 606. The first conductive layer 602 includes a first region 616 formed by an electrically continuous first conductor line 614. Tapers 622 of about 45 degrees are given to the outer-peripheral angles of 90-degree turned-around portions 620 of the electrically continuous first conductor line 614 and, at the same time, tapers 624 of about 45 degrees are given to the inner-peripheral angles corresponding to the tapers 622.

The second conductive layer 606 includes a second region 618 formed by an electrically continuous second conductor line 620. Tapers similar to those of the electrically continuous first conductor line 614 are also provided at the 90-degree turned-around portions of the electrically continuous second conductor line 620.

With the angles of the turned-around portions truncated like this, signals can be transmitted with greater facility from the viewpoint of parasitic capacity. Note also that although linear tapers are shown in FIG. 15 and FIG. 16, the shape of taper is not limited thereto and, for example, the edges may be rounded.

In the first and second embodiments, a description has been given of a case where the conductor line contained in the conductive layer has a thickness in the stacking direction shorter than its width in the surface direction (the cross-sectional shape being a horizontally-long rectangle), but the arrangement is not limited thereto. For example, the conductor line may be formed midway of a material of different material provided that the conductor line is electrically continuous. Also, the conductive layer may include a strip-shaped conductor line with a flat cross section, for example, one without branches, in the electrically continuous conductor line. In such a case, the arrangement of the conductor line in the filter region is the same as one described in the embodiments, so that the same advantageous effects can be obtained.

### Third Embodiment

With the wiring substrate according to the first and second embodiments, there is great attenuation of the common-mode signals in the high-frequency range, as shown in FIG. 3, FIG. 5, FIG. 7, and FIGS. 11A and 11B. Also, because of the structure, the higher the frequency is, the better the characteristics of the common-mode filter will be. In a third embodiment, a magnetic material layer 802 is provided on the opposite side of the wiring layer 4 and the conductive layer 8 of the wiring substrate 100 according to the first embodiment. This will not only enhance the bandpass characteristic in the high-frequency range, but also improve the bandpass characteristic in a lower-frequency range.

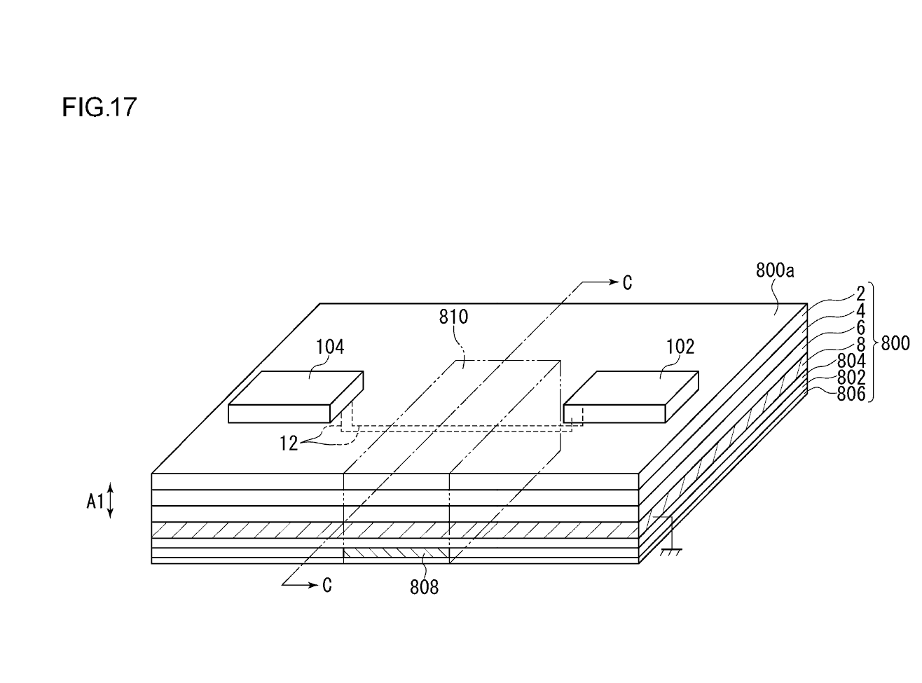

FIG. 17 is a perspective view schematically showing a wiring substrate 800 according to the third embodiment and an arrangement of modules mounted on the wiring substrate 800. A first semiconductor module 102 and a second semiconductor module 104 are mounted on a top surface 800a of the wiring substrate 800.

The wiring substrate 800 includes a stacked structure stacking a fourth insulating layer 806, a magnetic material layer 802, a third insulating layer 804, a conductive layer 8, a second insulating layer 6, a wiring layer 4, and a first insulating layer 2 in this order from the lower side. A pair of differential transmission lines 12 included in the wiring layer 4 passes across a filter region 810 (region delineated by two-dot chain lines in FIG. 17) of the wiring substrate 800. A magnetic material 808 is embedded in the magnetic material layer 802. The magnetic material 808 is formed of a magnetic material such as ferrite in such a manner as to cover the lower surface of the filter region 810. The thickness of the magnetic material layer 802 is designed to be 1 mm or less. The third insulating layer 804, the fourth insulating layer 806, and the components of the magnetic material layer 802 other than the magnetic material 808 are formed of an insulating material such as epoxy resin or alumina. The third insulating layer 804 provides insulation between the magnetic material 808 and the conductive layer 8.

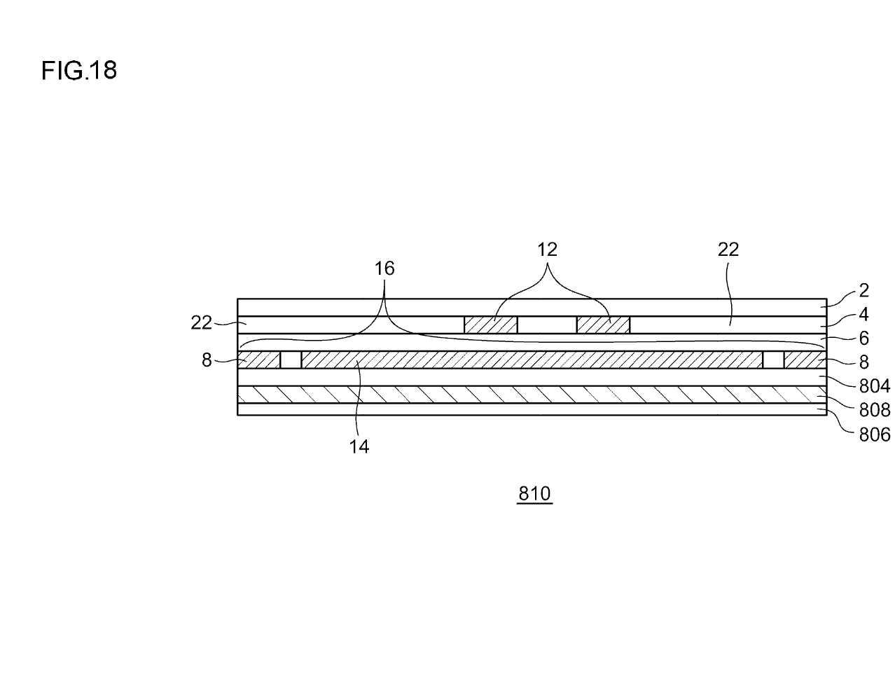

FIG. 18 is a cross-sectional view taken along the line C-C of FIG. 17. In FIG. 18, the depiction of components other than the filter region 810 is omitted. The magnetic material 808 is arranged below a region 16, formed by an electrically continuous conductive line 14 of the conductive layer 8, so that the magnetic material 808 is disposed counter to the region 16. The area of the magnetic material 808 may be approximately equal to the area of the region 16.

The wiring substrate 800 according to the third embodiment can achieve the same operation and advantageous effects as those of the wiring substrate 100 according to the first embodiment. In the wiring substrate 800 according to the third embodiment, the magnetic material 808 is additionally provided on the side opposite to the wiring layer 4 of the conductive layer 8. Thus, the induced current is more likely to flow through the conductor line 14 which is an inductor pattern formed in the conductive layer 8. In other words, the inductance of the conductor line 14 can be made larger. As a result, the bandpass characteristic is improved and therefore the common-mode signals can be filtered in a lower-frequency range. Further, the size of the conductor line 14 and the region 16 can be reduced by as much as the increased inductance, thereby contributing to the downsizing thereof.

In the third embodiment, a description has been given of a case where the magnetic material layer 802 is provided on the opposite side of the wiring layer 4 and the conductive layer 8 when the conductive layer 8 is provided on one surface of the wiring layer 4, but this should not be considered as limiting. For example, as for the wiring substrate 400 according to the second embodiment, a similar magnetic material layer may be provided at least one of above the first conductive layer 402 and under the second conductive layer 406 with an insulator layer disposed therebetween. In this case, too, the same operation and advantageous effects as those of the wiring substrate 100 according to the first embodiment can be achieved. The wiring substrate and the filter device 700 mounted on the mobile phone 1111 also achieves the same advantageous effects as those attained by the above-described embodiments.

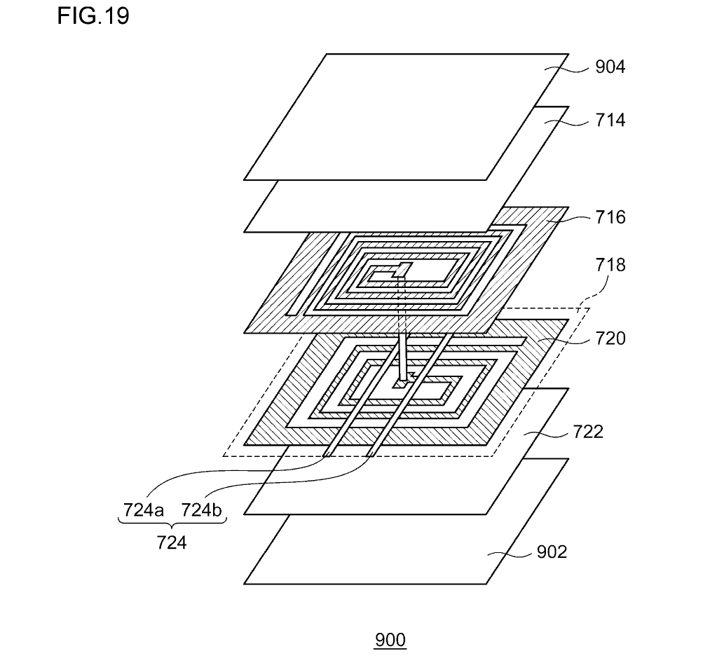

A filter device equipped with the magnetic material layer is now explained. FIG. 19 is an exploded perspective view showing a stacking structure inside the filter device. In FIG. 19, the depiction of insulating materials other than the first insulating layer 714 and the fourth insulating layer 722 is omitted.

A filter device 900 includes a stacked structure stacking a first magnetic material layer 902, a fourth insulating layer 722, a second conductive layer 720, a wiring layer 718, a first conductive layer 716, a first insulating layer 714, and a second magnetic material layer 904 in this order from the lower side. This stack structure of the filter device 900 corresponds to the stack structure of the filter device 700 except that the fourth insulating layer, the second conductive layer, the wiring layer, the first conductive layer and the first insulating layer are held by and between the two magnetic layers. The first magnetic material 902 and the second magnetic layer 904 are formed of a magnetic material such as ferrite in such a manner as to cover an inductor pattern formed on the second conductive layer 720 and an inductor pattern formed on the first inductive layer 716, respectively.

### DESCRIPTION OF THE REFERENCE NUMERALS

2 First insulating layer

4 Wiring layer

6 Second insulating layer

8 Conductive layer

10 Filter region

12 Differential transmission line pair

14 Conductor line

16 Region

100 Wiring substrate

102 First semiconductor module

104 Second semiconductor module

400 Wiring substrate

### INDUSTRIAL APPLICABILITY

A wiring substrate according to the present invention achieves a satisfactory bandpass characteristic in a high-frequency range.

1. A wiring substrate comprising:
a wiring layer including a pair of differential transmission lines;
a conductive layer where an electric potential thereof is fixed; and
an insulating layer provided between the wiring layer and the conductive layer,
wherein the conductive layer has a region formed by an electrically continuous conductor, and
wherein as seen from a stacking direction, the pair of transmission lines intersects with the conductor at a plurality of positions.

2. A wiring substrate according to claim 1, wherein at least part of the conductor is turned around a plurality of times in the region, and
wherein, as seen from the stacking direction, the pair of differential transmission lines intersects with a plurality of strip portions disposed counter to each other due to the turning-around of the conductor.

3. A wiring substrate according claim 2, wherein the plurality of strip portions are formed such that a first strip portion and a second strip portion, which differs from the first strip portion in width, are formed alternately.

4. A wiring substrate according to claim 1, wherein the region has a first region formed by a first electrically continuous conductor and a second region formed by a second electrically continuous conductor differing from the first conductor in width.

5. A wiring substrate according to claim 1, wherein at least part of the conductor is formed in a helical shape in the region.

6. A wiring substrate according to claim 1, further comprising a magnetic material layer provided on a side of the conductive layer, the side being opposite to the wiring layer.

7. A wiring substrate comprising:
a wiring layer including a pair of differential transmission lines;
a conductive layer, where an electric potential thereof is fixed, provided on one side of the wiring layer; and
an insulating layer provided between the wiring layer and the conductive layer;
another conductive layer, where an electric potential thereof is fixed, provided on the other side of the wiring layer; and
another insulating layer provided between the another conductive layer and the wiring layer,
wherein the conductive layer has a region formed by an electrically continuous conductor,
wherein as seen in a stacking direction, the pair of transmission lines intersects with the conductor at a plurality of positions,
wherein the another conductive layer has a region formed by another electrically continuous conductor, and
wherein as seen in the stacking direction, the pair of transmission lines intersects with the another conductor at a plurality of positions.

8. A wiring substrate according to claim 7, wherein the width of the conductor differs from that of the another conductor.

9. A wiring substrate according to claim 7, wherein an electric path having a starting point in the conductor and an end point in the another conductor is formed by way of a via that connects the conductor to the another conductor.

10. A wiring substrate according to claim 7, further comprising a magnetic material layer provided at least one of on a side of the conductive layer, the side being opposite to the wiring layer, and on a side of the another conductive layer, the side being opposite to the wiring layer.

11. A filter device comprising:
a wiring layer including a pair of differential transmission lines;
a conductive layer where an electric potential thereof is fixed;
an insulating layer provided between the wiring layer and the conductive layer;
a first external terminal connected to one end of one of the differential transmission line pair, the first external terminal being exposed on a surface of the filter device;
a second external terminal connected to the other end of one of the differential transmission line pair, the second external terminal being disposed on a surface of the filter device;
a third external terminal connected to one end of the other of the differential transmission line pair, the third external terminal being exposed on a surface of the filter device;
a fourth external terminal connected to the other end of the other of the differential transmission line pair, the fourth external terminal being disposed on a surface of the filter device; and
a fifth external terminal connected to the conductive layer, the fifth external terminal being exposed on a surface of the filter device,
wherein the conductive layer has a region formed by an electrically continuous conductor, and
wherein as seen in a stacking direction, the pair of transmission lines intersects with the conductor at a plurality of positions.

12. A portable device that mounts a wiring substrate according to claim 1.
